(19) United States
(12) Patent Application Publication
(10) Pub. No.: US 2026/0311763 A1
(43) Pub. Date: Oct. 8, 2026

(54) MEMORY STRUCTURE, MEMORY DEVICE AND OPERATING METHOD THEREOF

(71) Applicant: MACRONIX INTERNATIONAL CO., LTD., HSINCHU (TW)

(72) Inventors: Feng-Min LEE, Hsinchu City (TW); Yu-Yu LIN, New Taipei City (TW); Po-Hao TSENG, Taichung City (TW)

(21) Appl. No.: 19/098,032

(22) Filed: Apr. 2, 2025

(51) Int. Cl. G11C 16/10; G11C 16/08; G11C 16/24; G11C 16/26; H10B 43/27; H10D 30/69

(52) U.S. Cl. CPC G11C 16/10; G11C 16/08; G11C 16/24; G11C 16/26; H10B 43/27; H10D 30/694

(57) ABSTRACT

A memory device includes a plurality of memory cells. The plurality of memory cells includes a first memory cell. The first memory cell includes a first transistor and a first charge trap transistor. The first transistor is coupled to a first storage node, and is configured to transmit a first write bit line signal to the first storage node according to a first write word line signal. The first charge trap transistor is configured generate a first current signal according to a threshold voltage level of the first charge trap transistor and a voltage level of the storage node.

### BACKGROUND

### Technical Field

The present disclosure relates to a memory technique. More particularly, the present disclosure relates to a memory structure, a memory device and an operating method of a memory device.

### Description of Related Art

Regarding machine learning, a memory can perform training operations and inference operations. For training purpose, the memory need to have almost unlimited endurance to meet the huge weight update during training of big data. For inference purpose, the memory should have non-volatility and good retention to keep the weight fixed with low power consumption. However, so far, there is no universal memory suitable for training and inference in AI model. Thus, techniques associated with solving problems described above are important issues in the field.

### SUMMARY

The present disclosure provides a memory device. The memory device includes a plurality of memory cells. The plurality of memory cells includes a first memory cell. The first memory cell includes a first transistor and a first charge trap transistor. The first transistor is coupled to a first storage node, and is configured to transmit a first write bit line signal to the first storage node according to a first write word line signal. The first charge trap transistor is configured generate a first current signal according to a threshold voltage level of the first charge trap transistor and a voltage level of the storage node.

In some embodiments, when a voltage level of the first write word line signal is larger than a threshold voltage level of the first transistor, the first transistor is turned on, to perform a write operation, and when the voltage level of the first write word line signal is smaller than the threshold voltage level of the first transistor, the first transistor is turned off, to perform a read operation or retain a logic state of the first memory cell.

In some embodiments, a first terminal of the first charge trap transistor is configured to receive a first read word line signal, and a second terminal of the first charge trap transistor is configured to receive a first read bit line signal, when the first memory cell holds the logic state, a voltage level of the first read word line signal is equal to a voltage level of the first read bit line signal, and when the first memory cell performs the read operation, the voltage level of the first read word line signal is different from the voltage level of the first read bit line signal.

In some embodiments, when a first logic value is written into the first memory cell, a voltage level of the first write bit line signal is equal to the voltage level of the first write word line signal, when a second logic value is written into the first memory cell, the voltage level of the first write bit line signal is different from the voltage level of the first write word line signal, and the first logic value is different from the second logic value.

In some embodiments, the plurality of memory cells further comprises a second memory cell, the second memory cell comprising: a second transistor coupled to a second storage node, and configured to transmit a second write bit line signal to the second storage node according to the first write word line signal; and a second charge trap transistor configured generate a second current signal, wherein the first memory cell and the second memory cell are further configured to sum the first current signal and the second current signal.

In some embodiments, the memory device further includes: a first semiconductor structure elongated along a first direction; a second semiconductor structure elongated along the first direction, and separated from the first semiconductor structure along a second direction, and a first gate structure elongated along the second direction, and surrounding each of the first semiconductor structure and the second semiconductor structure, wherein the first gate structure and the first semiconductor structure are configured to operate as the first transistor, and the first gate structure and the second semiconductor structure are configured to operate as the second transistor.

In some embodiments, the memory device further includes: a third semiconductor structure coupled to the first semiconductor structure, and having a first length along the first direction; a fourth semiconductor structure coupled to the second semiconductor structure, having a second length larger than the first length along the first direction, and isolated from the third semiconductor structure along the second direction, wherein the third semiconductor structure and the fourth semiconductor structure are configured to transmit the first write bit line signal and the second write bit line signal, respectively.

In some embodiments, the plurality of memory cells further comprises a second memory cell, the second memory cell comprising: a second transistor coupled to a second storage node, and configured to transmit the first write bit line signal to the second storage node according to a second write word line signal; and a second charge trap transistor configured generate a second current signal, wherein the first memory cell and the second memory cell are further configured to sum the first current signal and the second current signal.

In some embodiments, the memory device further includes: a first semiconductor structure elongated along a first direction; a second semiconductor structure elongated along the first direction, and separated from the first semiconductor structure along a second direction, and a first gate structure elongated along a third direction, and surrounding the first semiconductor structure; a second gate structure elongated along the third direction, surrounding the second semiconductor structure, and separated from the first gate structure along the second direction, wherein the first gate structure and the first semiconductor structure are configured to operate as the first transistor, and the second gate structure and the second semiconductor structure are configured to operate as the second transistor.

In some embodiments, the memory device further includes: a conductive structure elongated along the second direction, and configured to transmit the first write bit line signal to each of the first semiconductor structure and the second semiconductor structure.

The present disclosure provides a memory structure. The memory structure includes a source structure, a drain structure, a first gate structure, a first semiconductor structure and a second gate structure. The source structure is elongated along a first direction. The drain structure is elongated along the first direction and separated from the source structure. The first gate structure surrounds each of the source structure and the drain structure and is configured to operate as a first charge trap transistor with the source structure and the drain structure. The first semiconductor structure is elongated along a second direction and coupled to the first gate structure. The second gate structure is separated from the first gate structure along the second direction, disposed above the first semiconductor structure and configured to operate as a first transistor with the first semiconductor structure.

In some embodiments, the memory structure further includes: a third gate structure surrounding each of the source structure and the drain structure and configured to operate as a second charge trap transistor with the source structure and the drain structure; and a second semiconductor structure elongated along the second direction, separated from the first semiconductor structure along the first direction, and coupled to the third gate structure.

In some embodiments, the second gate structure further surrounds the second semiconductor structure, and configured to operate as a second transistor with the second semiconductor structure, and a drain terminal of the second transistor is coupled to a gate terminal of the second charge trap transistor.

In some embodiments, the memory structure further includes: a third semiconductor structure coupled to the first semiconductor structure and having a first length along the second direction; and a fourth semiconductor structure coupled to the second semiconductor structure and having a second length along the second direction, the first length is smaller than the second length.

In some embodiments, the memory structure further includes: a first oxide structure having a third length along the second direction; and a second oxide structure having the first length along the second direction, and configured to isolate the third semiconductor structure and the fourth semiconductor structure from each other, wherein the first oxide structure the third semiconductor structure, the second oxide structure and the fourth semiconductor structure are arranged in order along the first direction.

In some embodiments, the memory structure further includes: a fourth gate structure separated from the second gate structure along the first direction, surrounding the second semiconductor structure, and configured to operate as a second transistor with the source structure and the second semiconductor structure, wherein each of the second gate structure and the fourth gate structure elongated along a third direction, and the first direction, the second direction and the third direction are perpendicular to each other.

In some embodiments, the memory structure further includes: a conductive structure elongated along the first direction, and configured to transmit a write bit line signal to each of the first semiconductor structure and the second semiconductor structure.

The present disclosure provides an operating method of a memory device. The operating method includes: writing a first input bit into a first storage node; storing a first weight bit by a first charge trap transistor coupled to the first storage node; and generating a first current signal flowing through the first charge trap transistor according to the first input bit and the first weight bit.

In some embodiments, the operating method further includes: turning on a first transistor by a write word line signal, to transmit a first write bit line signal to the first storage node; and turning on a second transistor by the write word line signal, to transmit a second write bit line signal to a second storage node, wherein the second storage node is different from the first storage node.

In some embodiments, the operating method further includes: turning on a first transistor by a first write word line signal, to transmit a write bit line signal to the first storage node; and turning on a second transistor by a second write word line signal, to transmit the write bit line signal to a second storage node, wherein the second storage node is different from the first storage node.

It is to be understood that both the foregoing general description and the following detailed description are examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a part of a memory device, illustrated according to some embodiments of present disclosure.

FIG. 2A is a schematic diagram of a part of a memory device, illustrated according to some embodiments of present disclosure.

FIG. 2B is a 3D schematic diagram of a part of a memory structure, illustrated according to some embodiments of present disclosure.

FIG. 2C is a cross sectional schematic diagram of further details of the memory structure, illustrated according to some embodiments of present disclosure.

FIG. 3A is a 3D schematic diagram of a part of a memory structure, illustrated according to some embodiments of present disclosure.

FIG. 3B is a cross sectional schematic diagram of further details of the memory structure, illustrated according to some embodiments of present disclosure.

FIG. 4A is a schematic diagram of the memory cell performing the write operation, illustrated according to some embodiments of present disclosure.

FIG. 4B is a schematic diagram of the memory cell performing the write operation, illustrated according to some embodiments of present disclosure.

FIG. 5A is a schematic diagram of the memory cell performing the read operation, illustrated according to some embodiments of present disclosure.

FIG. 5B is a schematic diagram of the memory cell performing the read operation, illustrated according to some embodiments of present disclosure.

FIG. 6A is a schematic diagram of a relationship between the write word line signal and a current level corresponding to the write transistor, illustrated according to some embodiments of present disclosure.

FIG. 6B is a schematic diagram of a relationship between the voltage level of the storage node and a current level corresponding to the read transistor, illustrated according to some embodiments of present disclosure.

FIG. 7A is a schematic diagram of a memory device, illustrated according to some embodiments of present disclosure.

FIG. 7B is a table of voltage levels of signals of the memory device under various conditions, illustrated according to some embodiments of present disclosure.

### DETAILED DESCRIPTION

In the present disclosure, when an element is referred to as “connected” or “coupled”, it may mean “electrically connected” or “electrically coupled”. “Connected” or “coupled” can also be used to indicate that two or more components operate or interact with each other. In addition, although the terms “first”, “second”, and the like are used in the present disclosure to describe different elements, the terms are used only to distinguish the elements or operations described in the same technical terms. The use of the term is not intended to be a limitation of the present disclosure.

Unless otherwise defined, all terms (including technical and scientific terms) used in the present disclosure have the same meaning as commonly understood by the ordinary skilled person to which the concept of the present invention belongs. It will be further understood that terms (such as those defined in commonly used dictionaries) should be interpreted as having a meaning consistent with its meaning in the related technology and/or the context of this specification and not it should be interpreted in an idealized or overly formal sense, unless it is clearly defined as such in this article.

The terms used in the present disclosure are only used for the purpose of describing specific embodiments and are not intended to limit the embodiments. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

Hereinafter multiple embodiments of the present disclosure will be disclosed with schema, as clearly stated, the details in many practices it will be explained in the following description. It should be appreciated, however, that the details in these practices is not applied to limit the present disclosure. Also, it is to say, in some embodiments of the present disclosure, the details in these practices are non-essential. In addition, for the sake of simplifying schema, some known usual structures and element in the drawings by a manner of simply illustrating for it.

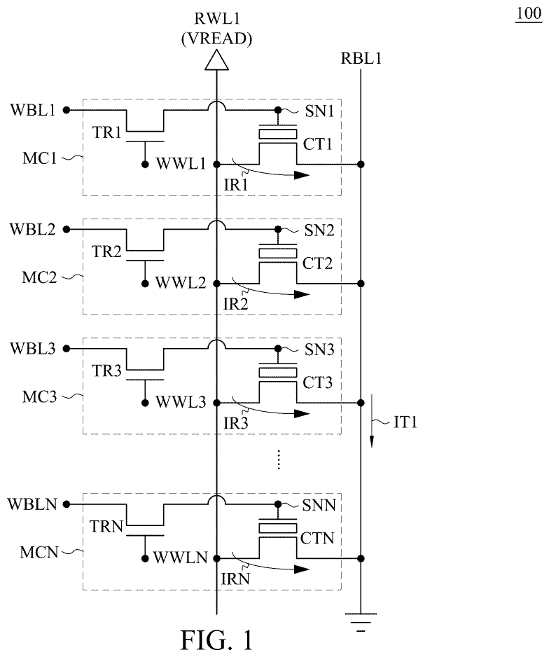

FIG. 1 is a schematic diagram of a part of a memory device 100, illustrated according to some embodiments of present disclosure. In some embodiments, the memory device 100 can be implemented by a three-dimensional (3D) AND array, to perform multiply-and-accumulate (MAC) operations.

In some embodiments, the memory device 100 can includes multiple memory cells, such as the memory cells MC1-MCN shown in FIG. 1, in which N is a positive integer. In some embodiments, the memory cells MC1-MCN are configured to store weight bits WB1-WBN.

As shown in FIG. 1, the memory cell MC1 includes a transistor TR1 and a charge trap transistor CT1. The memory cell MC2 includes a transistor TR2 and a charge trap transistor CT2. The memory cell MC3 includes a transistor TR3 and a charge trap transistor CT3, and so on. The memory cell MCN includes a transistor TRN and a charge trap transistor CTN. In some embodiments, the charge trap transistors CT1-CTN can trap various charges to have various threshold voltage levels.

In some embodiments, a terminal of the transistor TR1 is configured to receive a write bit line signal WBL1, another terminal of the transistor TR1 is coupled to a storage node SN1, and a control terminal of the transistor TR1 is configured to receive a write word line signal WWL1. A terminal of the charge trap transistor CT1 is configured to receive a read word line signal RWL1, another terminal of the charge trap transistor CT1 is configured to receive a read bit line signal RBL1, and a control terminal of the charge trap transistor CT1 is coupled to the storage node SN1.

Similarly, a terminal of the transistor TR2 is configured to receive a write bit line signal WBL2, another terminal of the transistor TR2 is coupled to a storage node SN2, and a control terminal of the transistor TR2 is configured to receive a write word line signal WWL2. A terminal of the charge trap transistor CT2 is configured to receive a read word line signal RWL1, another terminal of the charge trap transistor CT2 is configured to receive a read bit line signal RBL1, and a control terminal of the charge trap transistor CT2 is coupled to the storage node SN2, and so on. A terminal of the transistor TRN is configured to receive a write bit line signal WBLN, another terminal of the transistor TRN is coupled to a storage node SNN, and a control terminal of the transistor TRN is configured to receive a write word line signal WWLN. A terminal of the charge trap transistor CTN is configured to receive a read word line signal RWL1, another terminal of the charge trap transistor CTN is configured to receive a read bit line signal RBL1, and a control terminal of the charge trap transistor CTN is coupled to the storage node SNN.

In some embodiments, the transistors TR1-TRN are configured to perform the write operation, and are thus referred to as write transistors. The charge trap transistors CT1-CTN are configured to perform the read operation, and are thus referred to as read transistors. In some embodiments, the write bit line signals WBL1-WBLN are configured to carry the input bits IB1-IBN, respectively. The transistors TR1-TRN are configured to write the input bits IB1-IBN in to the storage nodes SN1-SNN.

During the read operation, the read bit line signal RBL1 has a ground voltage level, and the read word line signal RWL1 has a read voltage level VREAD larger than the ground voltage level, such that the charge trap transistors CT1-CTN generate current signals IR1-IRN, respectively. The current signals IR1-IRN flow through the charge trap transistors CT1-CTN, respectively. Then, the memory device 100 is configured to sum the current signals IR1-IRN to generate a total current signal IT1. Alternatively stated, a current level of the total current signal IT1 is equal to a summation of the current levels of the current signals IR1-IRN.

In some embodiments, the current levels of the current signals IR1-IRN are determined by the logic states of the charge trap transistors CT1-CTN. The logic states of the charge trap transistors CT1-CTN are determined by the threshold voltage level VCT of the charge trap transistor and the voltage level VSN of the storage node.

Specifically, when the voltage level VSN is larger than the threshold voltage levels VCT, a corresponding charge trap transistor is turned on, and a corresponding current signal has a current level HCL. When the voltage level VSN is smaller than the threshold voltage levels VCT, a corresponding charge trap transistor is turned off, and a corresponding current signal has a current level LCL. In which the current level HCL is larger than the current level LCL.

For example, when a voltage level VSN1 of the storage node SN1 is larger than a threshold voltage level VCT1 of the charge trap transistor CT1, the charge trap transistor CT1 is turned on, and the current signal IR1 has the current level HCL. When the voltage level VSN1 is smaller than the threshold voltage level VCT1, the charge trap transistor CT1 is turned off, and the current signal IR1 has the current level LCL.

Similarly, when a voltage level VSN2 of the storage node SN2 is larger than a threshold voltage level VCT2 of the charge trap transistor CT2, the charge trap transistor CT2 is turned on, and the current signal IR2 has the current level HCL. When the voltage level VSN2 is smaller than the threshold voltage level VCT2, the charge trap transistor CT2 is turned off, and the current signal IR2 has the current level LCL, and so on. When a voltage level VSNN of the storage node SNN is larger than a threshold voltage level VCTN of the charge trap transistor CTN, the charge trap transistor CTN is turned on, and the current signal IRN has the current level HCL. When the voltage level VSNN is smaller than the threshold voltage level VCTN, the charge trap transistor CTN is turned off, and the current signal IRN has the current level LCL.

In some embodiments, the charge trap transistors CT1-CTN can have various threshold voltage values to store weight bits WB1-WBN having various logic values, in which the various threshold voltage values correspond to various conductance of the charge trap transistors CT1-CTN. The storage nodes SN1-SNN can have various voltage values to store the input bits IB1-IBN having various logic values.

In summary, the current level of the current signal IR1 corresponds to a product of the logic value of the weight bit WB1 and the logic value of the input bit IB1. The current level of the current signal IR2 corresponds to a product of the logic value of the weight bit WB2 and the logic value of the input bit IB2, and so on. The current level of the current signal IRN corresponds to a product of the logic value of the weight bit WBN and the logic value of the input bit IBN. The current level of the total current signal IT1 corresponds to a summation of the products described above. As a result, the memory device 100 can perform the MAC operation to the weight bits WB1-WBN and the input bits IB1-IBN.

In some embodiments, the charge trap transistors CT1-CTN can be implemented by thin film transistors (TFT). The thin film transistors can be implemented by poly-silicon channel or oxide-semiconductor channel, such as indium oxide (InO), indium gallium zinc oxide (IGZO), indium tin oxide (ITO) or other material. In some embodiments, the memory cell can be manufactured by 3D stackable process.

In some embodiments, during the training operation of machine learning, the memory device 100 can perform operations of dynamic random-access memory (DRAM). The voltage level VSN of the storage node can be charged or discharge like a DRAM. The endurance of the memory device 100 is likely unlimited, and can perform MAC in non-destructive read mode.

In some embodiments, during the training operation of machine learning, the memory device 100 can perform operations of nonvolatile memory (NVM) mode. The threshold voltage level VCT of the read transistor is programmable and erasable, and can determine the logic value of the weight bit by higher voltage level VCT and lower voltage level VCT.

In some approaches, for training purpose, the memory need to have almost unlimited endurance to meet the huge weight update during training of big data. For inference purpose, the memory should have non-volatility and good retention to keep the weight fixed with low power consumption. However, the approaches described above are not suitable for training and inference simultaneously.

Compared to above approaches, in the embodiments of present disclosure. The memory device 100 has almost unlimited endurance, can perform nonvolatile operations, and has good retention. As a result, during machine learning, the memory device 100 has a better performance.

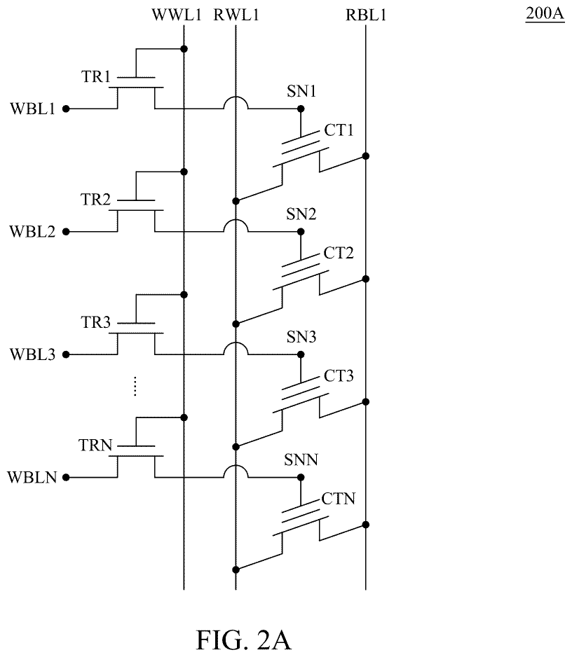

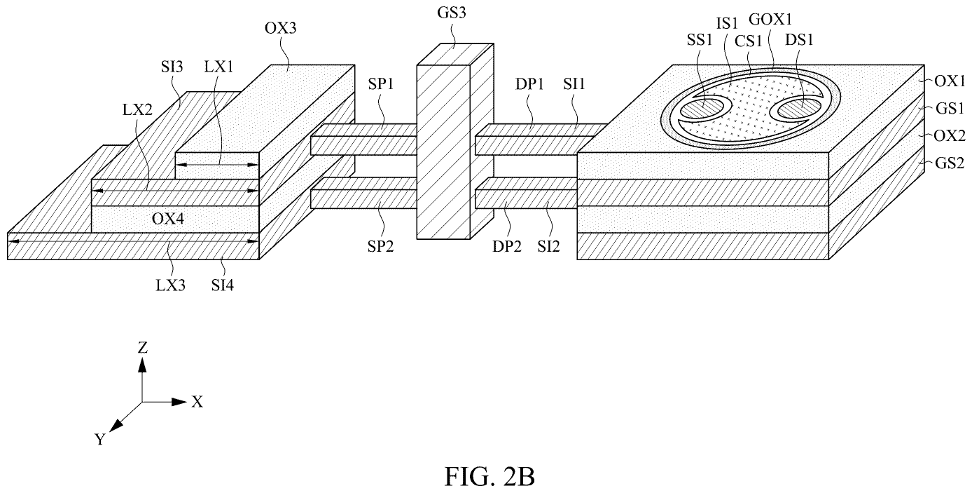

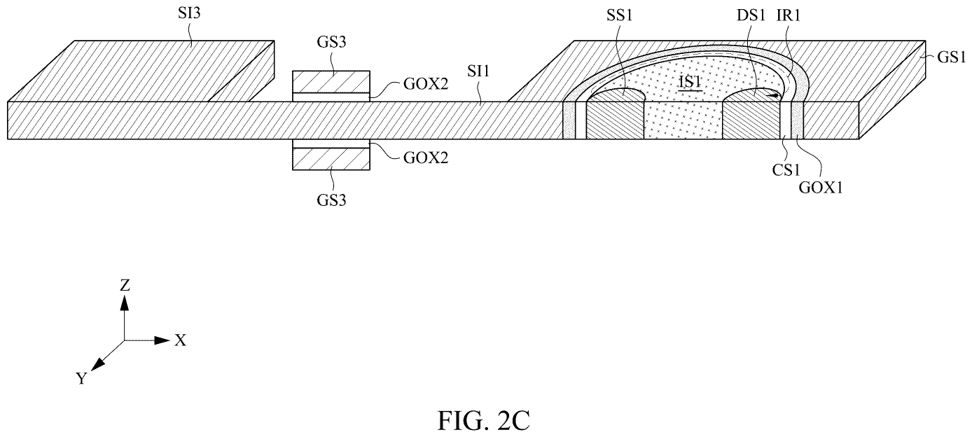

FIG. 2A is a schematic diagram of a part of a memory device 200A, illustrated according to some embodiments of present disclosure. Referring to FIG. 2A and FIG. 1, the memory device 200A is an alternative embodiment of the memory device 100. Elements of the memory device 200A follow a similar labeling convention to those of the memory device 100. For brevity, the discussion will focus more on differences between the memory device 200A and the memory device 100 than on similarities.

Compared to the memory device 100, in the memory device 200A, each of control terminals of the transistors TR1-TRN is configured to receive the write word line signal WWL1. Alternatively stated, the transistors TR1-TRN are turned on at the same time, and are turned off at the same time.

FIG. 2B is a 3D schematic diagram of a part of a memory structure 200B, illustrated according to some embodiments of present disclosure. In some embodiments, the memory structure 200B can be manufactured by stair case etching process or bit-cost etching process.

As shown in FIG. 2B, the memory structure 200B includes a source structure SS1, a drain structure DS1, an isolation structure IS1, a channel structure CS1, a gate oxide structure GOX1, gate structures GS1-GS3, oxide structures OX1-OX4 and semiconductor structures SI1-SI4.

In some embodiments, each of the source structure SS1 and the drain structure DS1 approximately has a cylindrical shape, and is elongated along a Z direction. The isolation structure IS1 is located between the source structure SS1 and the drain structure DS1, and is configured to isolate the source structure SS1 and the drain structure DS1 from each other. On an X-Y plane, the channel structure CS1 surrounds the isolation structure IS1, the source structure SS1 and the drain structure DS1, the gate oxide structure GOX1 surrounds the channel structure CS1, and each of the gate structures GS1-GS2 and the oxide structures OX1-OX2 surrounds the gate oxide structure GOX1. In some embodiments, the X direction, the Y direction and the Z direction are perpendicular to each other. Alternatively stated, the Z direction is perpendicular to the X-Y plane.

As shown in FIG. 2B, each of the gate structures GS1-GS2 and the oxide structures OX1-OX2 elongated along the X-Y plane. Along the Z direction, the oxide structure OX1, the gate structure GS1, the oxide structure OX2 and the gate structure GS2 are arranged in order. The oxide structure OX2 is configured to isolate the gate structures GS1 and GS2 from each other.

The semiconductor structures SI1 and SI2 are elongated along the X direction, and are separated from each other along the Z direction. The gate structure GS3 is elongated along the Z direction, and surrounds each of the semiconductor structures SI1 and SI2 on the Z-Y plane. The semiconductor structure SI1 includes a source portion SP1 and a drain portion DP1. The semiconductor structure SI2 includes a source portion SP2 and a drain portion DP2. Along the X direction, the source portions SP1 and SP2 are located at one side of the gate structure GS3, and the drain portions DP1 and DP2 are located at the other side of the gate structure GS3. Along the X direction, the gate structure GS3 is separated from each of the gate structures GS1 and GS2.

In some embodiments, the drain portions DP1 and DP2 are coupled to the gate structures GS1 and GS2, respectively. The source portions SP1 and SP2 are coupled to the semiconductor structures SI3 and SI4, respectively.

Along the Z direction, the oxide structure OX3, the semiconductor structure SI3, the oxide structure OX4 and the semiconductor structure SI4 are arranged in order. Each of the semiconductor structures SI3 and the oxide structures OX3 and OX4 is elongated along the X-Y plane. In some embodiments, the oxide structure OX4 is configured to isolate the semiconductor structures SI3 and SI4 from each other.

In some embodiments, the semiconductor structures SI3-SI4 and the oxide structures OX3-OX4 can have different lengths along the X direction, to form a stair shape. Specifically, along the X direction, the oxide structure OX3 has a length LX1, each of the oxide structure OX4 and the semiconductor structure SI3 has a length LX2, and the semiconductor structure SI4 has a length LX3. In which the length LX3 is larger than the length LX2, and the length LX2 is larger than the length LX1. As a result, the memory structure 200B can includes conductors contacting the semiconductor structures SI3-SI4 along the Z direction, to transmit corresponding signals to the semiconductor structures SI3-SI4.

Referring to FIG. 2A and FIG. 2B, the memory device can be implemented by the memory structure 200B. Specifically, the source structure SS1 can be implemented as source terminals of the charge trap transistors CT1-CTN, and is configured to receive the read word line signal RWL1. The drain structure DS1 can be implemented as drain terminals of the charge trap transistors CT1-CTN, and is configured to receive the read bit line signal RBL1. Alternatively stated, the memory structure 200B can sum the current signals IR1-IRN at the drain structure DS1. The gate structure GS1 can be implemented as a gate terminal of the charge trap transistor CT1, and coupled to the storage node SN1. The gate structure GS2 can be implemented as a gate terminal of the charge trap transistor CT2, and coupled to the storage node SN2.

On the other hand, the gate structure GS3 can be implemented as gate terminals of the transistor TR1-TRN, and are configured to receive the write word line signal WWL1. The drain portion DP1 can be implemented as a drain terminal of the transistor TR1, and is coupled to the storage node SN1. The drain portion DP1 can be implemented as a drain terminal of the transistor TR1, and is coupled to the storage node SN1. The drain portion DP2 can be implemented as a drain terminal of the transistor TR2, and is coupled to the storage node SN2. The source portions SP1 and SP2 can be implemented as a source terminal of the transistor TR1 and a source terminal of the transistor TR2, respectively. The semiconductor structure SI3 can receive the write bit line signal WBL1, and transmits the write bit line signal WBL1 to the source portion SP1. The semiconductor structure SI4 can receive the write bit line signal WBL2, and transmits the write bit line signal WBL2 to the source portion SP2.

In some embodiments, for the write transistors, the gate structure GS3 is referred to as a vertical word line, and the semiconductor structures SI3 and SI4 are referred to as horizontal bit lines.

In some embodiments, the channel structure CS1 can be implemented by silicon (Si) or other oxide semiconductor material. The gate structure GS3 can be implemented by Titanium oxide (TiN). Each of the semiconductor structures SI1-SI4 and the gate structure GS1-GS2 can be implemented by silicon (Si). In some alternative embodiments each of the semiconductor structures SI1-SI4 and the gate structure GS1-GS2 can be implemented by indium gallium zinc oxide (IGZO). The isolation structure can be implemented by dielectric material.

FIG. 2C is a cross sectional schematic diagram of further details of the memory structure 200B, illustrated according to some embodiments of present disclosure. As shown in FIG. 2C, the memory structure 200B further includes a gate oxide structure GOX2. On the Z-Y plane, the gate oxide structure GOX2 surrounds the semiconductor structure SI1, and the gate structure GS3 surrounds the gate oxide structure GOX2. Alternatively stated, the gate oxide structure GOX2 is located between the semiconductor structure SI1 and the gate structure GS3.

As shown in FIG. 2C, along the Z direction, a portion of the gate structure GS3 is disposed above the semiconductor structure SI1, and another portion of the gate structure GS3 is disposed below the semiconductor structure SI1. Furthermore, along the X direction, the gate structure GS3 is separated from the gate structure GS1.

Referring to FIG. 1 and FIG. 2C, during operation, the current signal IR1 flows from the source structure SS1 through the channel structure CS1 to the drain structure DS1. In some embodiments, the channel structure CS1 can be implemented by undoped silicon. The gate structure GS1 can be implemented by poly silicon.

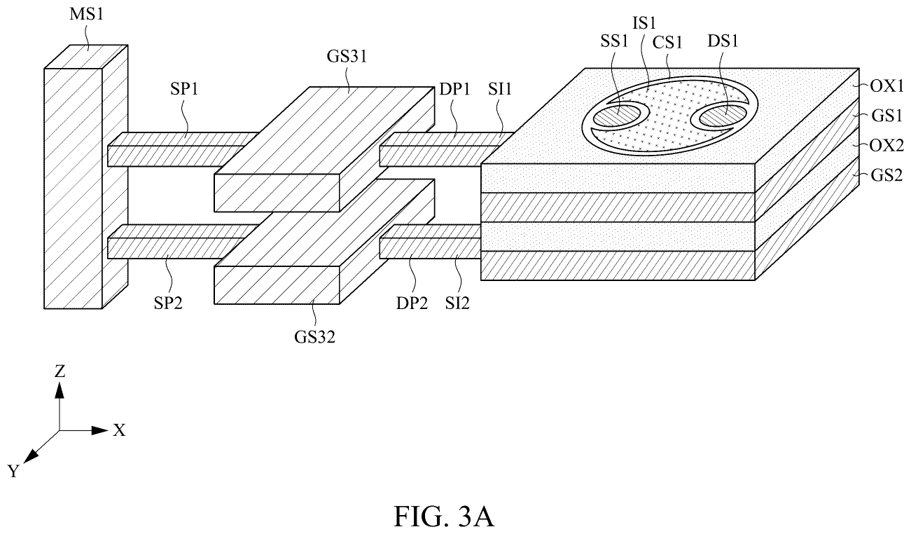

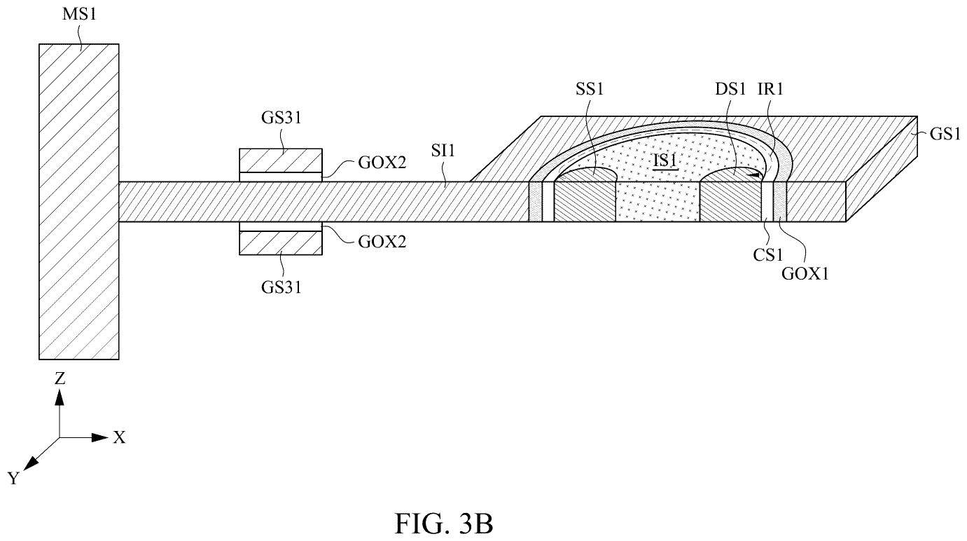

FIG. 3A is a 3D schematic diagram of a part of a memory structure 300A, illustrated according to some embodiments of present disclosure. Referring to FIG. 2B and FIG. 3A, the memory structure 300A is an alternative embodiment of the memory structure 200B. The memory structure 300A follows a similar labeling convention to that of the memory structure 200B. For brevity, the discussion will focus more on differences between the memory structure 300A and the memory structure 200B than on similarities.

Compared to the memory structure 200B, the memory structure 300A includes gate structures GS31, GS32 and a conductive structure MS1, instead of the gate structure GS3, the semiconductor structures SI3, SI4 and the oxide structures OX3, OX4.

As shown in FIG. 3A, on the Z-Y plane, the gate structures GS31 and GS32 surround the semiconductor structures SI1 and SI2, respectively, and separated from each other along the Z direction. Each of the gate structures GS31 and GS32 is elongated along the Y direction. Along the X direction, the source portion SP1 and the drain portion DP1 are located at two sides of the gate structure GS31, respectively, and the source portion SP2 and the drain portion DP2 are located at two sides of the gate structure GS32, respectively. The conductive structure MS1 is coupled to each of the source portion SP1 and the source portion SP2, and is elongated along the Z direction.

Referring to FIG. 1 and FIG. 3A, an alternative embodiment of the memory device 100 can be implemented by the memory structure 300A. In the alternative embodiment described above, each of the transistors TR1-TRN is configured to receive the write bit line signal WBL1. The conductive structure MS1 is configured to transmit the write bit line signal WBL1 to each of the source portion SP1 and the source portion SP2. The gate structure GS31 can be implemented as a gate terminal of the transistor TR1, and configured to receive the write word line signal WWL1. The gate structure GS32 can be implemented as a gate terminal of the transistor TR2, and configured to receive the write word line signal WWL2.

In some embodiments, for the write transistors, the gate structures GS31 and GS32 are referred to as horizontal word lines, and the conductive structure MS1 is referred to as a vertical bit line.

FIG. 3B is a cross sectional schematic diagram of further details of the memory structure 300A, illustrated according to some embodiments of present disclosure. Referring to FIG. 2C and FIG. 3B, the memory structure 300A is an alternative embodiment of the memory structure 200B. The memory structure 300A follows a similar labeling convention to that of the memory structure 200B. For brevity, the discussion will focus more on differences between the memory structure 300A and the memory structure 200B than on similarities.

As shown in FIG. 3B, on the Z-Y plane, the gate oxide structure GOX2 surrounds the semiconductor structure SI1, and the gate structure GS31 surrounds the gate oxide structure GOX2. Alternatively stated, the gate oxide structure GOX2 is located between the semiconductor structure SI1 and the gate structure GS31. Along the Z direction, a portion of the gate structure GS31 is disposed above the semiconductor structure SI1, and another portion of the gate structure GS31 is disposed below the semiconductor structure SI1. Furthermore, along the X direction, the gate structure GS31 is separated from the gate structure GS1.

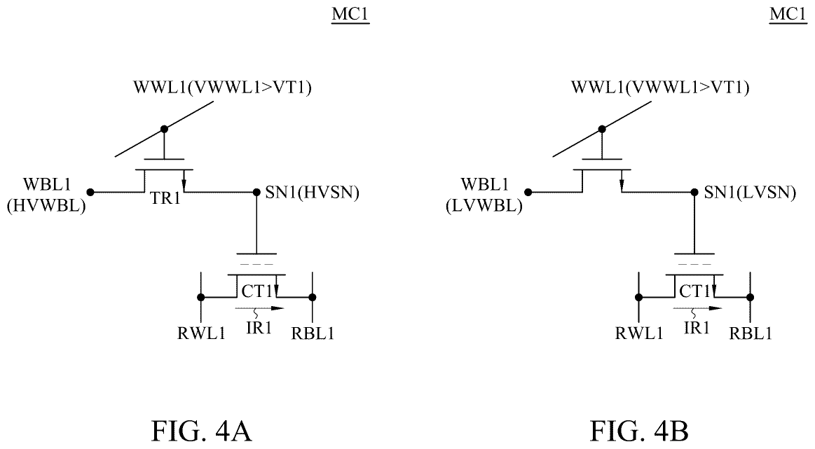

FIG. 4A is a schematic diagram of the memory cell MC1 performing the write operation, illustrated according to some embodiments of present disclosure. In some embodiments, the voltage level of the storage node SN1 can determine the logic state of the memory cell MC1. When the storage node SN1 is charged or discharged, the current signal IR1 can be adjusted. During the write operation, a voltage level VWWL1 of the write word line signal WWL1 is larger than a threshold voltage level VT1 of the transistor TR1, to turn on the transistor TR1, such that the write bit line signal WBL1 can charge or discharge the storage node SN1.

In some embodiments, the write bit line signal WBL1 is configured to carry the input bit IB1. In response to different logic values of the input bit IB1, the write bit line signal WBL1 has a voltage level HVWBL or a voltage level LVWBL, in which the voltage level HVWBL is larger than the voltage level LVWBL.

In the embodiment shown in FIG. 4A, the write bit line signal WBL1 has the voltage level HVWBL. Correspondingly, during the write operation, the storage node SN1 is charged to a voltage level HVSN.

FIG. 4B is a schematic diagram of the memory cell MC1 performing the write operation, illustrated according to some embodiments of present disclosure. Referring to FIG. 4B and FIG. 4A, the condition of FIG. 4B is an alternative embodiment of the condition of FIG. 4A. Therefore, for brevity, some descriptions are not repeated.

In the embodiment shown in FIG. 4B, the write bit line signal WBL1 has the voltage level LVWBL. Correspondingly, during the write operation, the storage node SN1 is discharged to a voltage level LVSN, in which the voltage level LVSN is smaller than the voltage level HVSN.

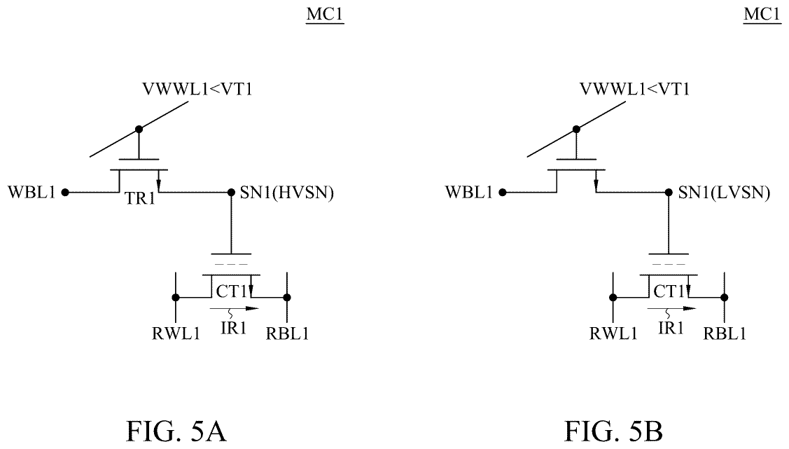

FIG. 5A is a schematic diagram of the memory cell MC1 performing the read operation, illustrated according to some embodiments of present disclosure. During the read operation, the voltage level VWWL1 of the write word line signal WWL1 is smaller than the threshold voltage level VT1. In some embodiments, the threshold voltage level VT1 can be larger than or equal to zero voltage level.

During the read operation, the voltage level VWWL1 is smaller than the threshold voltage level VT1, such that the transistor TR1 is turned off. At this moment, the charge trap transistor CT1 is turned on or turned off according to the voltage level of the storage node SN1. In the embodiment shown in FIG. 5A, the storage node SN1 has the voltage level HVSN, such that the charge trap transistor CT1 is turned on.

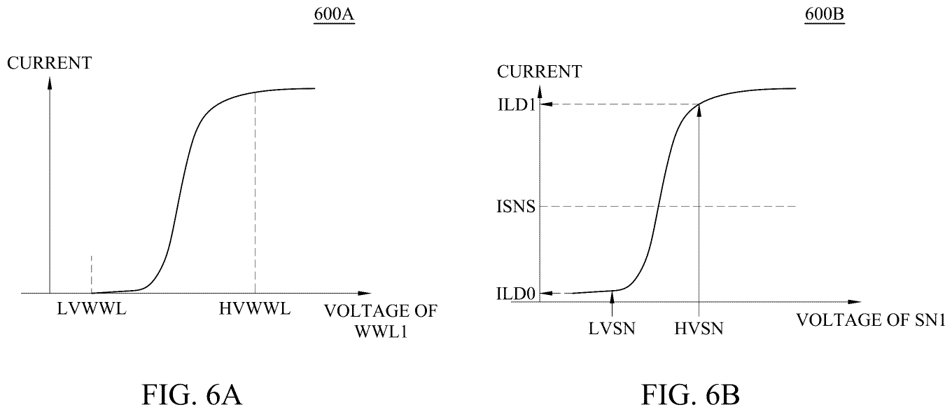

FIG. 5B is a schematic diagram of the memory cell MC1 performing the read operation, illustrated according to some embodiments of present disclosure. Referring to FIG. 5B and FIG. 5A, the condition of FIG. 5B is an alternative embodiment of the condition of FIG. 5A. Therefore, for brevity, some descriptions are not repeated. In the embodiment shown in FIG. 5B, the storage node SN1 has the voltage level LVSN, such that the charge trap transistor CT1 is turned off. Further details regarding the voltage levels HVSN and LVSN are described below in the embodiments associated with FIG. 6B.

FIG. 6A is a schematic diagram 600A of a relationship between the write word line signal WWL1 and a current level corresponding to the write transistor, illustrated according to some embodiments of present disclosure. A horizontal axis of the schematic diagram 600A corresponds to the voltage level of the write word line signal WWL1, that is, the gate voltage level of the transistor TR1. A vertical axis of the schematic diagram 600A corresponds to the current level of a current signal flowing through the transistor TR1.

Referring to FIG. 4A to FIG. 6A, the transistor TR1 has a threshold voltage level VT1. The word line signal WWL1 can have a voltage level HVWWL larger than the threshold voltage level VT1 or a voltage level LVWWL smaller than the threshold voltage level VT1. When the word line signal WWL1 has the voltage level HVWWL, the transistor TR1 is turned on, such that the memory cell MC1 can perform the write operation. When the word line signal WWL1 has the voltage level LVWWL, the transistor TR1 is turned off, such that the memory cell MC1 can retain logic states or perform the read operation.

FIG. 6B is a schematic diagram 600B of a relationship between the voltage level of the storage node SN1 and a current level corresponding to the read transistor, illustrated according to some embodiments of present disclosure. A horizontal axis of the schematic diagram 600B corresponds to the voltage level of the storage node SN1, that is, the gate voltage level of the charge trap transistor CT1. A vertical axis of the schematic diagram 600B corresponds to the current level of the current signal IR1 flowing through the charge trap transistor CT1.

Referring to FIG. 5A to FIG. 6A, when the storage node SN1 has the voltage level LVSN, the charge trap transistor CT1 is turned off, such that the current signal IR1 has a current level ILD0. In some embodiments, the current level ILD0 is the zero current level. When the storage node SN1 has the voltage level HVSN, the charge trap transistor CT1 is turned on, such that the current signal IR1 has a current level ILD1, in which the current level ILD1 is larger than the current level ILD0.

In some embodiments, the memory device 100 is further configured to compare the current level of the current signal IR1 with a sense current level ISNS, in which the sense current level ISNS is larger than the current level ILD0 and is smaller than the current level ILD1. When current level of the current signal IR1 is larger than the sense current level ISNS, the memory device 100 determines that the data of the storage node SN1 has a logic value 1. When current level of the current signal IR1 is smaller than the sense current level ISNS, the memory device 100 determines that the data of the storage node SN1 has a logic value 0.

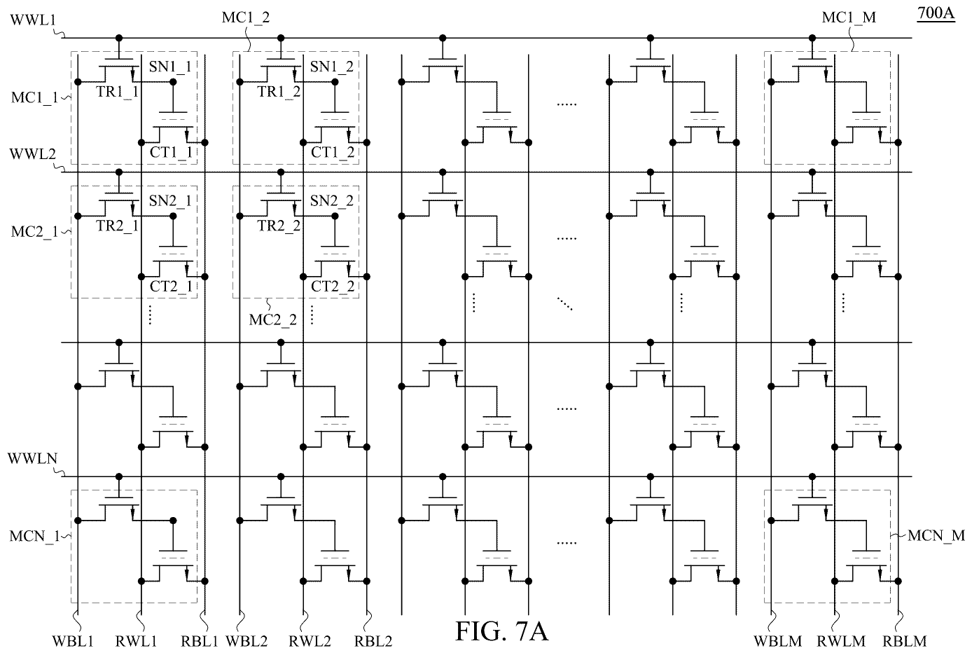

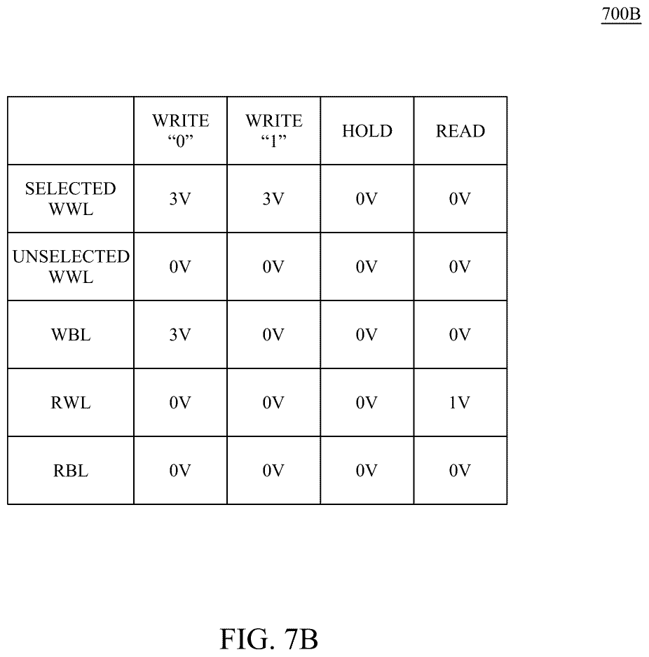

FIG. 7A is a schematic diagram of a memory device 700A, illustrated according to some embodiments of present disclosure. In some embodiments, the memory device 700A can be implemented by 3D memory array. Referring to FIG. 1 and FIG. 7A, the memory device 700A is an alternative embodiment of the memory device 100. For brevity, the discussion will focus more on differences between the memory device 700A and the memory device 100 than on similarities.

As shown in FIG. 7A, the memory device 700A includes memory cells MC1_1-MCN_M. It is noted that M and N at the end of MCN_M are positive integer. Each of the memory cells MC1_1-MCN_1 is configured to receive the write bit line signal WBL1, the read word line signal RWL1 and the read bit line signal RBL1. Each of the memory cells MC1_2-MCN_2 is configured to receive the write bit line signal WBL2, the read word line signal RWL2 and the read bit line signal RBL2, and so on. Each of the memory cells MC1_M-MCN_M is configured to receive the write bit line signal WBLM, the read word line signal RWLM and the read bit line signal RBLM.

Similarly, each of the memory cells MC1_1-MC1_M is configured to receive the write word line signal WWL1. Each of the memory cells MC2_1-MC2_M is configured to receive the write word line signal WWL2, and so on. Each of the memory cells MCN_1-MCN_M is configured to receive the write word line signal WWLN.

In some embodiments, each of the memory cells MC1_1-MCN_M includes two transistors. For example, the memory cell MC1_1 includes a transistor TR1_1 and a charge trap transistor CT1_1. The memory cell MC1_2 includes a transistor TR1_2 and a charge trap transistor CT1_2. The memory cell MC2_1 includes a transistor TR2_1 and a charge trap transistor CT2_1. The memory cell MC2_2 includes a transistor TR2_2 and a charge trap transistor CT2_2.

As shown in FIG. 7A, a terminal of the transistor TR1_1 is configured to receive the write bit line signal WBL1, another terminal of the transistor TR1_1 is coupled to a storage node SN1_1, and a control terminal of the transistor TR1_1 is configured to receive the write word line signal WWL1. A terminal of the charge trap transistor CT1_1 is configured to receive the read word line signal RWL1, another terminal of the charge trap transistor CT1_1 is configured to receive the read bit line signal RBL1, and a control terminal of the charge trap transistor CT1_1 is coupled to the storage node SN1_1.

Similarly, a terminal of the transistor TR1_2 is configured to receive the write bit line signal WBL2, another terminal of the transistor TR1_2 is coupled to a storage node SN1_2, and a control terminal of the transistor TR1_2 is configured to receive the write word line signal WWL1. A terminal of the charge trap transistor CT1_2 is configured to receive the read word line signal RWL2, another terminal of the charge trap transistor CT1_2 is configured to receive the read bit line signal RBL2, and a control terminal of the charge trap transistor CT1_2 is coupled to the storage node SN1_2.

Similarly, a terminal of the transistor TR2_1 is configured to receive the write bit line signal WBL1, another terminal of the transistor TR2_1 is coupled to a storage node SN2_1, and a control terminal of the transistor TR2_1 is configured to receive the write word line signal WWL2. A terminal of the charge trap transistor CT2_1 is configured to receive the read word line signal RWL1, another terminal of the charge trap transistor CT2_1 is configured to receive the read bit line signal RBL1, and a control terminal of the charge trap transistor CT2_1 is coupled to the storage node SN2_1.

Similarly, a terminal of the transistor TR2_2 is configured to receive the write bit line signal WBL2, another terminal of the transistor TR2_2 is coupled to a storage node SN2_2, and a control terminal of the transistor TR2_2 is configured to receive the write word line signal WWL2. A terminal of the charge trap transistor CT2_2 is configured to receive the read word line signal RWL2, another terminal of the charge trap transistor CT2_2 is configured to receive the read bit line signal RBL2, and a control terminal of the charge trap transistor CT2_2 is coupled to the storage node SN2_2.

Referring to FIG. 7A and FIG. 3A, the memory device 700A can be implemented by the memory structure 300A. Specifically, the drain structure DS1 can operate as drain terminals of the charge trap transistors CT1_1 and CT2_1, and be configured to receive the read bit line signal RBL1. The source structure SS1 can operate as source terminals of the charge trap transistors CT1_1 and CT2_1, and be configured to receive the read word line signal RWL1. The gate structure GS1 can operate as a gate terminal of the charge trap transistor CT1_1, and be coupled to the storage node SN1_1. The gate structure GS2 can operate as a gate terminal of the charge trap transistor CT2_1, and be coupled to the storage node SN2_1.

On the other hand, the gate structure GS31 can operate as a gate terminal of the transistor TR1_1, and be configured to receive the write word line signal WWL1. The gate structure GS32 can operate as a gate terminal of the transistor TR2_1, and be configured to receive the write word line signal WWL2. The drain portion DP1 can operate as a drain terminal of the transistor TR1_1, and be coupled to the storage node SN1_1. The drain portion DP2 can operate as a drain terminal of the transistor TR2_1, and be coupled to the storage node SN2_1. The source portion SP1 can operate as a source terminal of the transistor TR1_1. The source portion SP2 can operate as a source terminal of the transistor TR2_1. The conductive structure MS1 is configured to receive the write bit line signal WBL1, and transmit the write bit line signal WBL1 to each of the source portions SP1 and SP2.

Referring to FIG. 1 and FIG. 7A, the memory device 700A is an alternative embodiment of the memory device 100. The memory cells MC1-MCN can be implemented by the memory cells MC1_1-MCN_1. Alternatively stated, the memory cells MC1_1-MCN_1 can generate the current signals IR1-IRN, respectively, and sum the current signals IR1-IRN.

FIG. 7B is a table 700B of voltage levels of signals of the memory device 700A under various conditions, illustrated according to some embodiments of present disclosure. As shown in FIG. 7B, the table 700B shows voltage levels of a selected write word line signal (WWL), an unselected write word line signal, a write bit line signal (WBL), a read word line signal (RWL) and a read bit line signal (RBL) under various conditions.

For illustration purpose, operations of the memory cell MC1_1 is described as an example. In this example, the selected WWL is the write word line signal WWL1. The unselected write word line signal is the write word line signals WWL2-WWLN. The WBL is the write bit line signal WBL1. The RWL is the word line signal RWL1. The RBL is the read bit line signal RBL1.

Referring to FIG. 7B and FIG. 7A, when writing the logic value 0 into the memory cell MC1_1, the selected write word line signal WWL1 has a voltage level of 3 volts (3V), such that the transistor TR1_1 is turned on. In response to writing the logic value 0, the write bit line signal WBL1 has a voltage level of 3 volts. At this moment, each of the unselected write word line signals WWL2-WWLN, the word line signal RWL1 and the read bit line signal RBL1 has a voltage level of 0 volt (0V).

In contrast, when writing the logic value 1 into the memory cell MC1_1, the selected write word line signal WWL1 has the voltage level of 3 volts, such that the transistor TR1_1 is turned on. In response to writing the logic value 1, the write bit line signal WBL1 has the voltage level of 0 volt. At this moment, each of the unselected write word line signals WWL2-WWLN, the word line signal RWL1 and the read bit line signal RBL1 has the voltage level of 0 volt.

When the memory cell MC1_1 holds the logic state, the selected write word line signal WWL1 has the voltage level of 0 volt, such that the transistor TR1_1 is turned off. Correspondingly, the storage node SN1_1 can hold the logic state of the memory cell MC1_1. At this moment, each of the unselected write word line signals WWL2-WWLN, the write bit line signal WBL1, the word line signal RWL1 and the read bit line signal RBL1 has the voltage level of 0 volt.

When the read operation is performed to the memory cell MC1_1, the read word line signal RWL1 has a voltage level of 1 volt (1V), and the read bit line signal RBL1 has the voltage level of 0 volt, such that two terminals of the charge trap transistor CT1_1 have a voltage difference. Correspondingly, the charge trap transistor CT1_1 generates a corresponding current signal according to the logic state of the memory cell MC1_1. At this moment, each of the unselected write word line signals WWL1-WWLN and the write bit line signal WBL1 has the voltage level of 0 volt.

Referring to FIG. 4A, FIG. 4B and the FIG. 7B, in some embodiments, the memory cell MC1_1 can be implemented by the memory cell MC1, the transistor TR1_1 can be implemented by the transistor TR1, and the charge trap transistor CT1_1 can be implemented by the charge trap transistor CT1.

In the embodiments described above, the voltage level HVWBL can be equal to the voltage level of 3 volts, the voltage level LVWBL can be equal to the voltage level of 0 volt, and the threshold voltage level can be between the voltage level of 0 volt and the voltage level of 3 volts.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising a plurality of memory cells, the plurality of memory cells comprising a first memory cell, the first memory cell comprising:
a first transistor coupled to a first storage node, and configured to transmit a first write bit line signal to the first storage node according to a first write word line signal; and
a first charge trap transistor configured generate a first current signal according to a threshold voltage level of the first charge trap transistor and a voltage level of the storage node.

2. The memory device of claim 1, wherein
when a voltage level of the first write word line signal is larger than a threshold voltage level of the first transistor, the first transistor is turned on, to perform a write operation, and
when the voltage level of the first write word line signal is smaller than the threshold voltage level of the first transistor, the first transistor is turned off, to perform a read operation or retain a logic state of the first memory cell.

3. The memory device of claim 2, wherein a first terminal of the first charge trap transistor is configured to receive a first read word line signal, and a second terminal of the first charge trap transistor is configured to receive a first read bit line signal,
when the first memory cell holds the logic state, a voltage level of the first read word line signal is equal to a voltage level of the first read bit line signal, and
when the first memory cell performs the read operation, the voltage level of the first read word line signal is different from the voltage level of the first read bit line signal.

4. The memory device of claim 2, wherein
when a first logic value is written into the first memory cell, a voltage level of the first write bit line signal is equal to the voltage level of the first write word line signal,
when a second logic value is written into the first memory cell, the voltage level of the first write bit line signal is different from the voltage level of the first write word line signal, and
the first logic value is different from the second logic value.

5. The memory device of claim 1, wherein the plurality of memory cells further comprises a second memory cell, the second memory cell comprising:
a second transistor coupled to a second storage node, and configured to transmit a second write bit line signal to the second storage node according to the first write word line signal; and
a second charge trap transistor configured generate a second current signal,
wherein the first memory cell and the second memory cell are further configured to sum the first current signal and the second current signal.

6. The memory device of claim 5, further comprising:
a first semiconductor structure elongated along a first direction;
a second semiconductor structure elongated along the first direction, and separated from the first semiconductor structure along a second direction; and
a first gate structure elongated along the second direction, and surrounding each of the first semiconductor structure and the second semiconductor structure,
wherein the first gate structure and the first semiconductor structure are configured to operate as the first transistor, and
the first gate structure and the second semiconductor structure are configured to operate as the second transistor.

7. The memory device of claim 6, further comprising:
a third semiconductor structure coupled to the first semiconductor structure, and having a first length along the first direction; and
a fourth semiconductor structure coupled to the second semiconductor structure, having a second length larger than the first length along the first direction, and isolated from the third semiconductor structure along the second direction,
wherein the third semiconductor structure and the fourth semiconductor structure are configured to transmit the first write bit line signal and the second write bit line signal, respectively.

8. The memory device of claim 1, wherein the plurality of memory cells further comprises a second memory cell, the second memory cell comprising:
a second transistor coupled to a second storage node, and configured to transmit the first write bit line signal to the second storage node according to a second write word line signal; and
a second charge trap transistor configured generate a second current signal,
wherein the first memory cell and the second memory cell are further configured to sum the first current signal and the second current signal.

9. The memory device of claim 8, further comprising:
a first semiconductor structure elongated along a first direction;
a second semiconductor structure elongated along the first direction, and separated from the first semiconductor structure along a second direction, and
a first gate structure elongated along a third direction, and surrounding the first semiconductor structure; and
a second gate structure elongated along the third direction, surrounding the second semiconductor structure, and separated from the first gate structure along the second direction,
wherein the first gate structure and the first semiconductor structure are configured to operate as the first transistor, and
the second gate structure and the second semiconductor structure are configured to operate as the second transistor.

10. The memory device of claim 9, further comprising:
a conductive structure elongated along the second direction, and configured to transmit the first write bit line signal to each of the first semiconductor structure and the second semiconductor structure.

11. A memory structure, comprising:
a source structure elongated along a first direction;
a drain structure elongated along the first direction and separated from the source structure;
a first gate structure surrounding each of the source structure and the drain structure and configured to operate as a first charge trap transistor with the source structure and the drain structure;
a first semiconductor structure elongated along a second direction and coupled to the first gate structure; and
a second gate structure separated from the first gate structure along the second direction, disposed above the first semiconductor structure and configured to operate as a first transistor with the first semiconductor structure.

12. The memory structure of claim 11, further comprising:
a third gate structure surrounding each of the source structure and the drain structure and configured to operate as a second charge trap transistor with the source structure and the drain structure; and
a second semiconductor structure elongated along the second direction, separated from the first semiconductor structure along the first direction, and coupled to the third gate structure.

13. The memory structure of claim 12, wherein the second gate structure further surrounds the second semiconductor structure, and configured to operate as a second transistor with the second semiconductor structure, and
a drain terminal of the second transistor is coupled to a gate terminal of the second charge trap transistor.

14. The memory structure of claim 13, further comprising:
a third semiconductor structure coupled to the first semiconductor structure and having a first length along the second direction; and
a fourth semiconductor structure coupled to the second semiconductor structure and having a second length along the second direction,
the first length is smaller than the second length.

15. The memory structure of claim 14, further comprising:
a first oxide structure having a third length along the second direction; and
a second oxide structure having the first length along the second direction, and configured to isolate the third semiconductor structure and the fourth semiconductor structure from each other,
wherein the first oxide structure the third semiconductor structure, the second oxide structure and the fourth semiconductor structure are arranged in order along the first direction.

16. The memory structure of claim 12, further comprising:
a fourth gate structure separated from the second gate structure along the first direction, surrounding the second semiconductor structure, and configured to operate as a second transistor with the source structure and the second semiconductor structure,
wherein each of the second gate structure and the fourth gate structure elongated along a third direction, and
the first direction, the second direction and the third direction are perpendicular to each other.

17. The memory structure of claim 16, further comprising:
a conductive structure elongated along the first direction, and configured to transmit a write bit line signal to each of the first semiconductor structure and the second semiconductor structure.

18. An operating method of a memory device, comprising:
writing a first input bit into a first storage node;
storing a first weight bit by a first charge trap transistor coupled to the first storage node; and
generating a first current signal flowing through the first charge trap transistor according to the first input bit and the first weight bit.

19. The operating method of claim 18, further comprising:
turning on a first transistor by a write word line signal, to transmit a first write bit line signal to the first storage node; and
turning on a second transistor by the write word line signal, to transmit a second write bit line signal to a second storage node,
wherein the second storage node is different from the first storage node.

20. The operating method of claim 18, further comprising:
turning on a first transistor by a first write word line signal, to transmit a write bit line signal to the first storage node; and
turning on a second transistor by a second write word line signal, to transmit the write bit line signal to a second storage node,
wherein the second storage node is different from the first storage node.
